(19) United States
(12) Patent Application Publication
(10) Pub. No.: US 2025/0069777 A1
(43) Pub. Date: Feb. 27, 2025

(54) FLEXIBLE FLAT CONNECTION CABLE WITH EFFECT OF CIRCUIT PROTECTION AND MANUFACTURING METHOD THEREOF

(71) Applicant: BOZHOU LANTO ELECTRONIC LIMITED, Anhui (CN)

(72) Inventors: AiQing WU, Anhui (CN); MingChao ZHANG, Anhui (CN); Kai WANG, Anhui (CN)

(73) Assignee: BOZHOU LANTO ELECTRONIC LIMITED, Anhui (CN)

(21) Appl. No.: 18/941,168

(22) Filed: Nov. 8, 2024

Related U.S. Application Data
(63) Continuation of application No. PCT/CN2022/091619, filed on May 9, 2022.

(51) Int. Cl. H01B 7/08; H01B 7/17; H01B 13/06

(52) U.S. Cl. CPC H01B 7/0838; H01B 7/17; H01B 13/06

(57) ABSTRACT

A flexible flat connection cable with an effect of circuit protection and a manufacturing method thereof are provided. The flexible flat connection cable with the effect of circuit protection may be implemented by stamping techniques, etching techniques or laser engraving techniques and include a plurality of flexible flat conductive wires and an insulation covering component. Each flexible flat conductive wire includes at least one circuit protection structure which includes two circuit conductive parts, a circuit protection part disposed between the two circuit conductive parts, and two circuit connection parts each of which is connected to the circuit conductive part and the circuit protection part. The circuit conductive part has a first line width, and the circuit protection part has a second line width less than the first line width. The insulation covering component encompasses the circuit protection structures of the plurality of flexible flat conductive wires.

### CROSS-REFERENCE TO RELATED APPLICATIONS

This application claims the priority benefit of PCT publication number WO/2023/216045, filed on May 9, 2022, the full disclosure of which is incorporated herein by reference.

### TECHNICAL FIELD OF THE INVENTION

The present disclosure is related to a structure and a manufacturing method of a flexible flat connection cable and is particularly related to a flexible flat connection cable with an effect of circuit protection and a manufacturing method thereof.

### DESCRIPTION OF THE PRIOR ART

A flexible flat cable (FFC) is formed by a flexible flat conductive wire that is placed between two insulation sheets and then is pressed and is configured to connect to an electronic device to transmit electrical signals by disposing electrical connectors on the two ends thereof. The FFC has many advantages such as arbitrary bending and folding, less thickness, small volume, easy connection and easily solving electromagnetic shielding. However, the current FFC usually allows an overcurrent pass and is unable to have an effect on circuit protection.

### SUMMARY

The embodiments of the present disclosure are to provide a flexible flat connection cable with an effect of circuit protection and a manufacturing method thereof where a circuit protection structure with less line width (smaller cross-sectional area) is disposed. When the current passing through the flexible flat cable is excessive, the circuit protection structure is fused to form a broken circuit for protecting circuits and electronic components.

The flexible flat connection cable with the effect of the circuit protection in one embodiment of the present disclosure includes a plurality of flexible flat conductive wires and an insulation covering component. The plurality of flexible flat conductive wires are arranged to extend in parallel to each other and be separated by preset intervals. Each of the plurality of flexible flat conductive wires includes at least one circuit protection structure, and the at least one circuit protection structure includes two circuit conductive parts, a circuit protection part disposed between the two circuit conductive parts, and two circuit connection parts each of which is connected to one of the circuit conductive parts and the circuit protection part. The circuit conductive part has a first line width, the circuit protection part has a second line width, and the first line width is greater than the second line width. The plurality of flexible flat conductive wires are disposed within the insulation covering component, and the insulation covering component encompasses the circuit protection structures of the plurality of flexible flat conductive wires. The position of the circuit protection part of each of the plurality of flexible flat conductive wires and the position of the circuit protection part of the adjacent flexible flat conductive wire are staggered in the direction orthogonal to the extending direction of the flexible flat conductive wire.

Preferably, the positions of the circuit protection parts of the plurality of flexible flat conductive wires are all staggered in the direction orthogonal to the extending direction of the flexible flat conductive wire.

The line width of each of the circuit connection parts gradually increases from one end connected to the circuit protection part to one end connected to the circuit conductive part.

Each of the circuit connection parts exhibits a cone, and the conical degree range of the cone is 30 degrees to 60 degrees.

The second line width is one eighth to one twelfth of the first line width.

The second line width is one tenth of the first line width, and the second line width is equal to the thickness of each of the plurality of flexible flat conductive wires.

The insulation covering component includes a first insulation sheet and a second insulation sheet which are relatively disposed, and the first insulation sheet and the second insulation sheet are clamped and encompass the plurality of flexible flat conductive wires.

Each of the plurality of flexible flat conductive wires and the corresponding circuit protection structure in one embodiment of the present disclosure are an integrally stamped component, an integrally etched component or an integrally laser engraved component.

The manufacturing method of the flexible flat connection cable with the effect of the circuit protection in one embodiment of the present disclosure includes a conductive bulk provision step, a circuit protection structure formation step and an insulation covering component formation step. In the conductive bulk provision step, providing a conductive bulk. In the circuit protection structure formation step, forming a plurality of separate circuit protection structures on at least one part of the conductive bulk, wherein each of the plurality of circuit protection structures includes a circuit protection part, two circuit conductive parts respectively connected to two sides of the circuit protection part, and two circuit connection parts connected to the circuit protection part and the two circuit conductive parts. In the insulation covering component formation step, forming an insulation covering component which encompasses the plurality of circuit protection structures. The circuit conductive part has a first line width, the circuit protection part has a second line width, the first line width is greater than the second line width, and the position of the circuit protection part of each of the plurality of circuit protection structures and the position of the circuit protection part of the adjacent circuit protection structure are staggered in the direction orthogonal to the extending direction of the circuit conductive part.

The conductive bulk in one embodiment of the present disclosure is a conductive plate, and the manufacturing method further includes a flexible flat conductive wire formation step: continuing and forming the circuit conductive parts on the part of the conductive bulk except the plurality of circuit protection structures so that the circuit conductive parts on the two sides of the circuit protection part extend along the direction far away from the circuit protection part to form a plurality of flexible flat conductive wires.

The insulation covering component formation step includes: attaching the plurality of flexible flat conductive wires with the plurality of circuit protection structures to a first insulation sheet; pressing a second insulation sheet on the plurality of flexible flat conductive wires and the first insulation sheet.

The circuit protection structure formation step and the flexible flat conductive wire formation step in one embodiment of the present disclosure are respectively implemented by a double continuous stamped process.

The circuit protection structure formation step and the flexible flat conductive wire formation step in another embodiment of the present disclosure are implemented by etching techniques or laser engraving techniques, and the circuit protection structure formation step and the flexible flat conductive wire formation step are synchronously complete.

The conductive bulk in another embodiment of the present disclosure is a plurality of conductive wires, and the manufacturing method of the present embodiment further includes a wire pressing extension step: pressing and extending the plurality of conductive wires to form a plurality of flexible flat conductive wires; wherein each of the plurality of separate circuit protection structures respectively forms on each of the plurality of flexible flat conductive wires.

The circuit protection structure formation step is implemented by stamping techniques, etching techniques or laser engraving techniques.

In another embodiment of the present disclosure, each of the plurality of flexible flat conductive wires and the corresponding circuit protection structure form an integrally stamped component, an integrally etched component or an integrally laser engraved component by stamping, etching or laser engraving.

The manufacturing method of the present embodiment further includes a flexible flat conductive wire positioning step: attaching the plurality of flexible flat conductive wires to a first insulation sheet, and positioning the plurality of flexible flat conductive wires on the first insulation sheet; the insulation covering component formation step further includes: attaching a second insulation sheet to the plurality of flexible flat conductive wires and the first insulation sheet.

The manufacturing method of the present embodiment further includes: a flexible flat conductive wire positioning step: attaching the plurality of flexible flat conductive wires to a positioning sheet, and positioning the plurality of flexible flat conductive wires on the positioning sheet; wherein the circuit protection structure formation step further includes: forming the circuit protection structure on each of the plurality of flexible flat conductive wires by stamping techniques so that the flexible flat conductive wire and the circuit protection structure become an integrally stamped component; wherein the insulation covering component formation step further includes: attaching a first insulation sheet and a second insulation sheet to the plurality of flexible flat conductive wires and the plurality of circuit protection structures.

The manufacturing method of the present embodiment further includes: a positioning sheet remove step: removing the positioning sheet after forming the plurality of circuit protection structures.

The line width of each of the circuit connection parts gradually increases from one end connected to the circuit protection part to one end connected to the circuit conductive part.

In the flexible flat connection cable with the effect of the circuit protection and the manufacturing method thereof, the circuit protection structure is formed on the flexible flat conductive wire and includes the circuit conductive part with the greater first line width and the circuit protection part with the less second line width. When the current passing through the flexible flat cable exceeds the maximum current which is allowable for the circuit protection structure, the circuit protection structure is fused to form the broken circuit, thereby protecting each electronic component of the circuits.

The circuit protection part of each of the plurality of flexible flat conductive wires and the circuit protection part of the adjacent flexible flat conductive wire are arranged in the direction orthogonal to the extending direction of the flexible flat conductive wire by staggering the positions thereof so that the part of each flexible flat conductive wire which is the weakest structure is dispersedly disposed; the part of each flexible flat conductive wire which is the weakest structure can be intensified by the adjacent flexible flat conductive wire so that the entire structure of the plurality of flexible flat conductive wires still remains the preset strength to enhance the bendable degree of the product.

The circuit connection part of which the line width gradually increases from the second line width to the first line width is disposed between the circuit conductive part and the circuit protection part; the structure of the circuit connection part with the gradually increasing line width can avoid stress concentration and prevent the flexible flat conductive wire from breaking on the connection point of the circuit conductive part and the circuit protection part to increase the tension of each flexible flat conductive wire which can bear.

### BRIEF DESCRIPTION OF DRAWINGS

The accompanying drawings herein is provided to have a further understanding on the present application and constitutes one part of the present application. The schematic embodiments and the description of the present application is used to explain the present application instead of constituting inappropriate limitations. In the drawings:

FIG. 1 is a 3D exploded view diagram of a flexible flat connection cable with an effect of circuit protection according to one embodiment of the present disclosure.

FIG. 2 is the top view diagram and the partial enlargement view diagram of the flexible flat connection cable with the effect of the circuit protection after removing a first insulation sheet of FIG. 1.

FIG. 3 is a flowchart of a manufacturing method of a flexible flat connection cable with an effect of circuit protection according to one embodiment of the present disclosure.

FIG. 4 to FIG. 8 are the schematic view diagrams implementing the manufacturing method of FIG. 3 by stamping techniques.

FIG. 9 to FIG. 12 are the schematic view diagrams implementing the manufacturing method of FIG. 3 by etching techniques or laser engraving techniques.

FIG. 13 is a flowchart of a manufacturing method of a flexible flat connection cable with an effect of circuit protection according to another embodiment of the present disclosure.

FIG. 14 to FIG. 18 are the schematic view diagrams implementing the manufacturing method of FIG. 13 by stamping techniques, etching techniques or laser engraving techniques.

FIG. 19 is a flowchart of a manufacturing method of a flexible flat connection cable with an effect of circuit protection according to yet another embodiment of the present disclosure.

FIG. 20 to FIG. 25 are the schematic view diagrams implementing the manufacturing method of FIG. 13 by stamping techniques.

### DETAILED DESCRIPTION

The technical solutions in the embodiments of the present disclosure will be described clearly and completely below in conjunction with the accompanying drawings in the embodiments of the present disclosure. Apparently, the described embodiments are merely one part of the embodiments of the present disclosure and are not all embodiments of the present disclosure. Based on the embodiments of the present disclosure, all other embodiments obtained by a person skilled in the art without inventive steps shall fall within the scope of protection of the present disclosure.

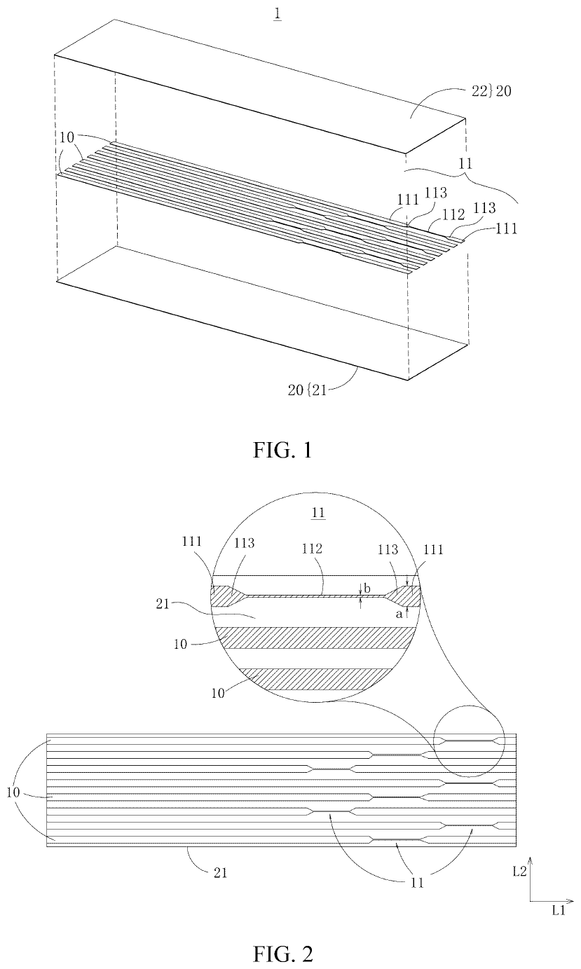

Please refer to FIG. 1 and FIG. 2, wherein FIG. 1 is a 3D exploded view diagram of a flexible flat connection cable with an effect of circuit protection according to one embodiment of the present disclosure, and FIG. 2 is the top view diagram and the partial enlargement view diagram of the flexible flat connection cable with the effect of the circuit protection after removing a first insulation sheet of FIG. 1. As shown in the figures, a flexible flat connection cable 1 with an effect of circuit protection includes a plurality of flexible flat conductive wires 10 and an insulation covering component 20. The plurality of flexible flat conductive wires 10 are disposed within the insulation covering component 20, and the insulation covering component 20 entirely encompasses the plurality of flexible flat conductive wires 10. The insulation covering component 20 located on two ends of the flexible flat conductive wire 10 may be peeled to be electrically connected to a electrical connector. The plurality of flexible flat conductive wires 10 are composed of metal materials such as oxygen-free copper, and the insulation covering component 20 is composed of insulation materials such as a PET film coated with thermoplastic resin with fire retardant characteristics.

The plurality of flexible flat conductive wires 10 are arranged to extend in parallel to each other and be separated by preset intervals, and each of the plurality of flexible flat conductive wires 10 includes at least one circuit protection structure 11. The circuit protection structure 11 in the present embodiment includes two circuit conductive parts 111, a circuit protection part 112 disposed between the two circuit conductive parts 111, and two circuit connection parts 113 each of which is connected to the circuit conductive part 111 and the circuit protection part 112. The circuit conductive part 111 has a first line width a, the circuit protection part 112 has a second line width b, and the first line width a is greater than the second line width b.

Because the second line width b of the circuit protection part 112 is less than the first line width a of the circuit conductive part 111, and the resistance of a conductor is proportional to the length of the conductor and is inversely proportional to the cross-sectional area of the conductor, the less the cross-sectional area of the conductor is, the greater the resistance value of the conductor is, and the line width of the conductor is related to the cross-sectional area of the conductor, the resistance value of the circuit protection part 112 is greater than the resistance value of the circuit conductive part 111. When the same current passes through the circuit conductive parts 111 and the circuit protection part 112, the heat generated by the circuit protection part 112 is more. Hence, in normal operation, electrical signals would be transmitted along the circuit conductive parts 111, the circuit connection parts 113 and the circuit protection part 112, and the circuit protection part 112 would be fused due to the heat generation thereof so that a circuit loop is transformed into a broken circuit to have the effect on the circuit protection when the current exceeds a rated standard. The second line width b of the circuit protection part 112 may be determined according to design requirements and be set as one eighth to one twelfth of the first line width; the second line width b in the present embodiment is one tenth of the first line width a, and the second line width b in the present embodiment is equal to the thickness of the flexible flat conductive wire 10.

The line width of each of the circuit connection parts 113 gradually increases from one end connected to the circuit protection part 112 to one end connected to the circuit conductive part 111, and gradually increases by linear increase. In other words, each of the circuit connection parts 113 exhibits a cone, and the conical degree of the cone is 45 degrees. In some embodiments, the conical degree range of the cone of each circuit connection part 113 may be 30 degrees to 60 degrees. By disposing the conical circuit connection part 113 between the circuit conductive part 111 and the circuit protection part 112, when the flexible flat conductive wire 10 undergoes force to be extended, the force is smoothly transmitted from the circuit conductive part 111 to the circuit protection part 112 along the circuit connection part 113 and then is smoothly transmitted from the circuit protection part 112 to the circuit conductive part 111 along another circuit connection part 113. In comparison with the structure that the circuit conductive part is directly connected to the circuit protection part to form a right angle without the circuit connection part 113, the circuit connection part 113 of the present embodiment can avoid stress concentration on the connection point, thereby preventing the flexible flat conductive wire 10 from breaking on the connection point of the circuit conductive part 111 and the circuit protection part 112 and increasing the tension of each flexible flat conductive wire 10 which can bear.

Although the present embodiment implements the circuit protection part 112 with the less second line width b by forming recessions on two sides of the flexible flat conductive wire 10 and the circuit connection part 113 exhibits the cone, the flexible flat connection cable 1 with the effect of the circuit protection is not limited thereto. In the other embodiments, the entire line width of the circuit protection part less than the entire line width of the circuit conductive part may be implemented by forming slots or openings in the flexible flat conductive wire 10 to have the effect on the circuit protection.

In addition, the position of the circuit protection part 112 of each of the plurality of flexible flat conductive wires 10 and the position of the circuit protection part 112 of the adjacent flexible flat conductive wire 10 are staggered in the direction L2 orthogonal to the extending direction L1 of the flexible flat conductive wire 10. Preferably, all the positions of the circuit protection parts 112 of the plurality of flexible flat conductive wires 10 are even staggered in the direction L2 orthogonal to the extending direction L1 of the flexible flat conductive wire 10. In other words, the projection of each circuit protection part 112 on the direction L2 would not overlap any projection of the other circuit protection parts 112 on the direction L2. The projection on the direction L2 of the circuit protection part 112 of each flexible flat conductive wire 10 of the present embodiment would overlap the projection on the direction L2 of the circuit protection parts 112 of two third flexible flat conductive wire 10 each of which is separated from the corresponding flexible flat conductive wire 10 by the two flexible flat conductive wire 10 on one side of the corresponding flexible flat conductive wire 10.

The circuit protection part 112 of each flexible flat conductive wire 10 and the circuit protection part 112 of the adjacent flexible flat conductive wire 10 are arranged in the direction L2 orthogonal to the extending direction L1 of the flexible flat conductive wire 10 by staggering the positions thereof so that the part of each flexible flat conductive wire 10 which is the weakest structure is dispersedly disposed; the part of each flexible flat conductive wire 10 which is the weakest structure can be intensified by the adjacent flexible flat conductive wire 10 so that the entire structure of the plurality of flexible flat conductive wires 10 still remains the preset strength to enhance the bendable degree of the product.

The insulation covering component 20 of the present embodiment includes a first insulation sheet 21 and a second insulation sheet 22 which are relatively disposed, and the first insulation sheet 21 and the second insulation sheet 22 are clamped and pressed against each other by hot pressing techniques and encompass the plurality of flexible flat conductive wires 10 and entirely encompass the circuit protection structure 11. For example, the first insulation sheet 21 and the second insulation sheet 22 may be the PET films coated with thermoplastic resin with fire retardant characteristics.

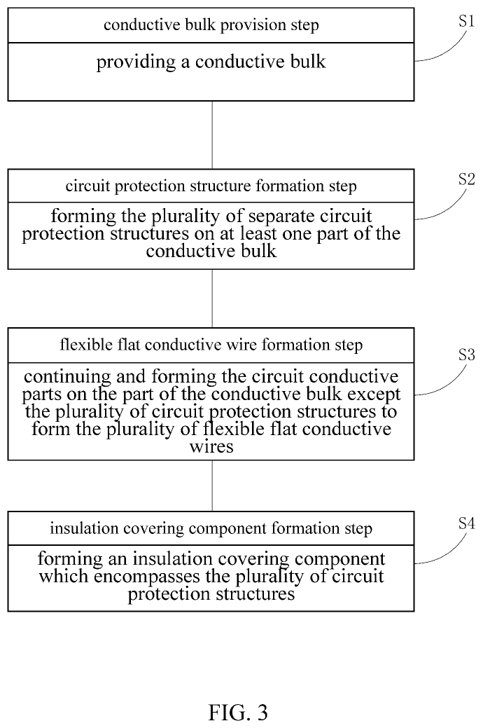

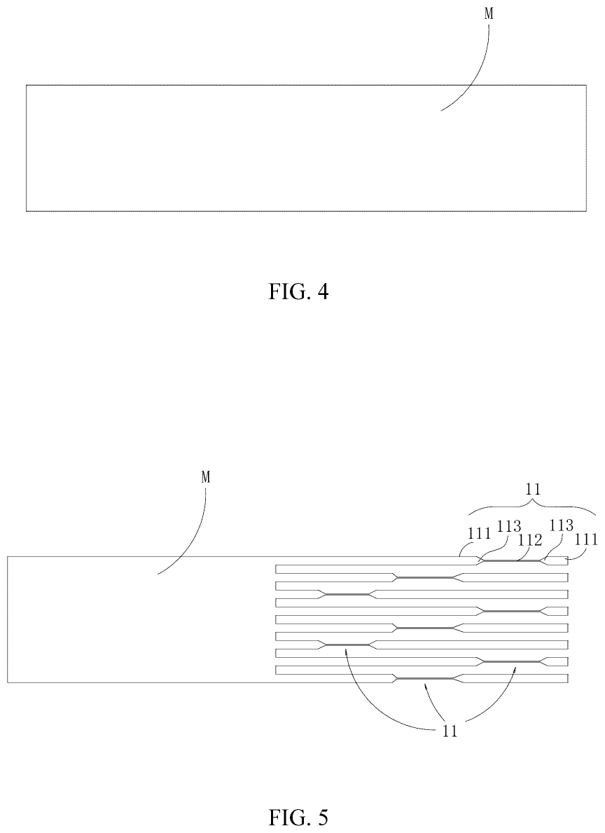

Please refer to FIG. 3, which is a flowchart of a manufacturing method of a flexible flat connection cable with an effect of circuit protection according to one embodiment of the present disclosure. Please refer FIG. 4 to FIG. 8, which are the schematic view diagrams implementing the manufacturing method of FIG. 3 by stamping techniques. First, step S1 is a conductive bulk provision step, and in step S1, a conductive bulk M is provided. As shown in FIG. 4, the conductive bulk is a conductive plate, and the conductive plate of the present embodiment is an oxygen-free copper plate. Step S2 is subsequently performed.

Step S2 is a circuit protection structure formation step. In step S2, as shown in FIG. 5, the conductive bulk M is placed on a stamping machine to stamp and form a plurality of separate circuit protection structures 11 on one part of the conductive bulk M by a first die. Each of the plurality of circuit protection structures 11 includes a circuit protection part 112, two circuit conductive parts 111 respectively connected to two sides of the circuit protection part 112, and a circuit connection part 113 connected to the circuit protection part 112 and the circuit conductive part 111. Step S3 is subsequently performed.

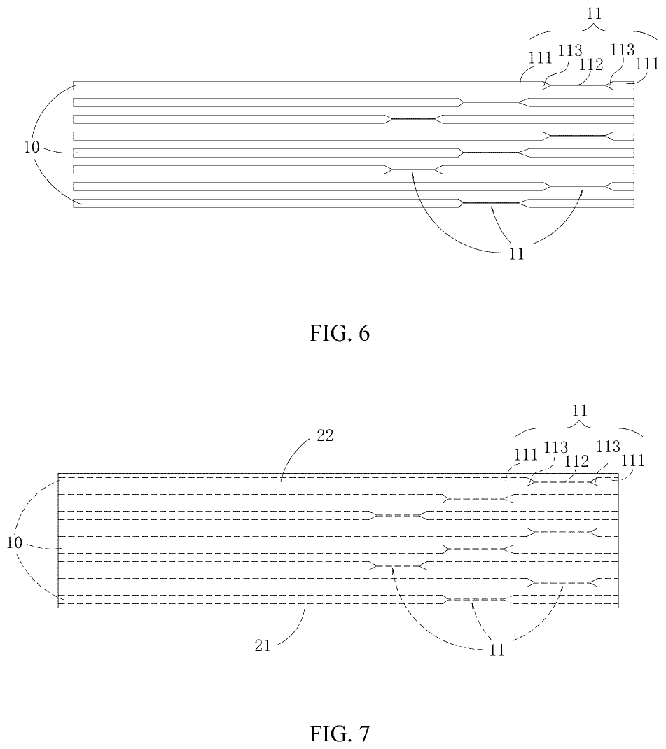

Step S3 is a flexible flat conductive wire formation step. In step S2, as shown in FIG. 6, the part of the conductive bulk M except the plurality of circuit protection structures 11 is stamped by a second die, and the circuit conductive parts 111 continue and extend from the circuit conductive parts 111 of the circuit protection structures 11 so that the circuit conductive parts 111 on the two sides of the circuit protection part 113 extend along the direction far away from the circuit protection part to form a plurality of flexible flat conductive wires 10. In some embodiments, each flexible flat conductive wire 10 and the corresponding circuit protection structure 11 form an integrally stamped component. Step S4 is subsequently performed.

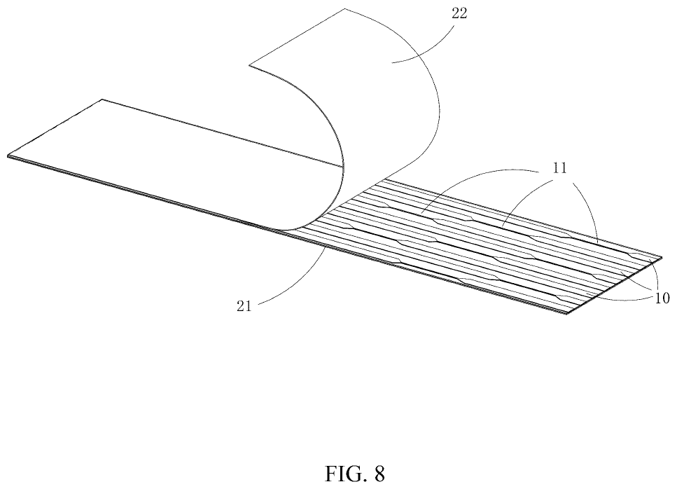

Step S4 is an insulation covering component formation step. In step S2, as shown in FIG. 7, the insulation covering component 20 which entirely encompasses the plurality of circuit protection structures 11 is formed. As shown in FIG. 8, step S4 further includes two steps as follows: attaching the plurality of flexible flat conductive wires 10 with the plurality of circuit protection structures 11 to the first insulation sheet 21; pressing the second insulation sheet 22 on the plurality of flexible flat conductive wires 10 and the first insulation sheet 21 by hot pressing techniques to form the insulation covering component 20 which entirely encompasses the plurality of circuit protection structures 11.

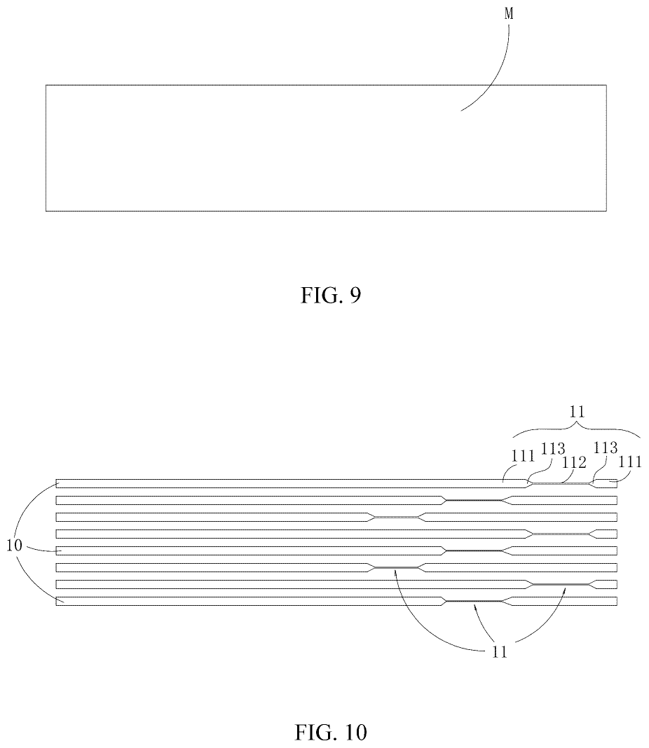

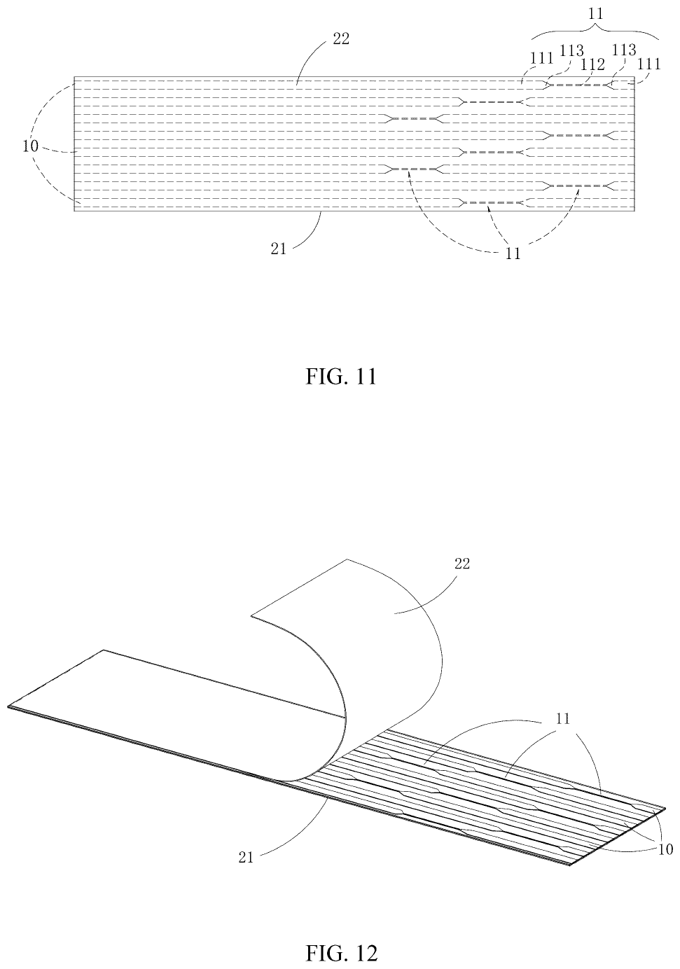

Please refer to FIG.9 to FIG. 12, which are the schematic view diagrams implementing the manufacturing method of FIG. 3 by etching techniques or laser engraving techniques. As shown in FIG. 9, in step 1 (the conductive bulk provision step), the conductive bulk M is provided and is the conductive plate, and the conductive plate of the present embodiment is the oxygen-free copper plate. Afterwards, as shown in FIG. 10, the circuit protection structure 11 and the entire flexible flat conductive wire 10 are synchronously formed by etching techniques or laser engraving techniques, and in other words, step S2 (the circuit protection structure formation step) and step S3 (the flexible flat conductive wire formation step) are synchronously complete. In some embodiments, each flexible flat conductive wire 10 and the corresponding circuit protection structure 11 are an integrally etched component or an integrally laser engraved component. Afterwards, as shown in FIG. 11, in step S4 (the insulation covering component formation step), the insulation covering component 20 which entirely encompasses the plurality of circuit protection structures 11 is formed. As shown in FIG. 12, the plurality of flexible flat conductive wires 10 with the plurality of circuit protection structures 11 would be attached to the first insulation sheet 21, and then, the second insulation sheet 22 would be pressed on the plurality of flexible flat conductive wires 10 and the first insulation sheet 21 by the hot pressing techniques.

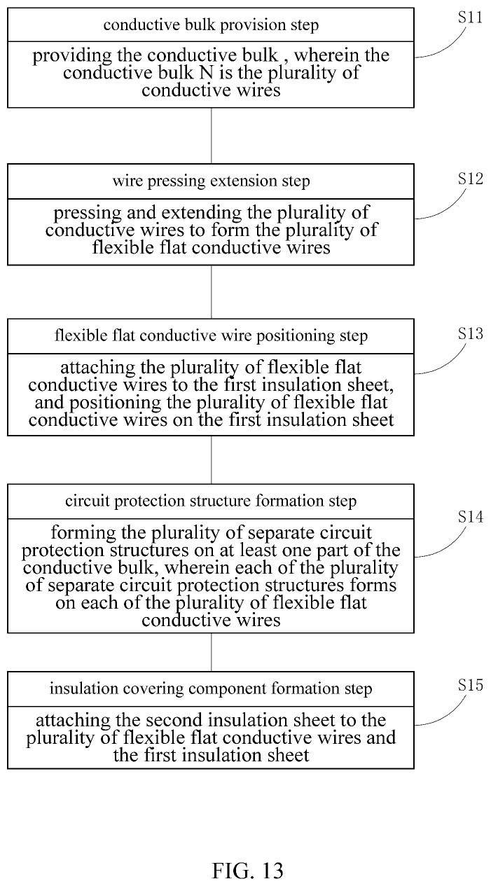

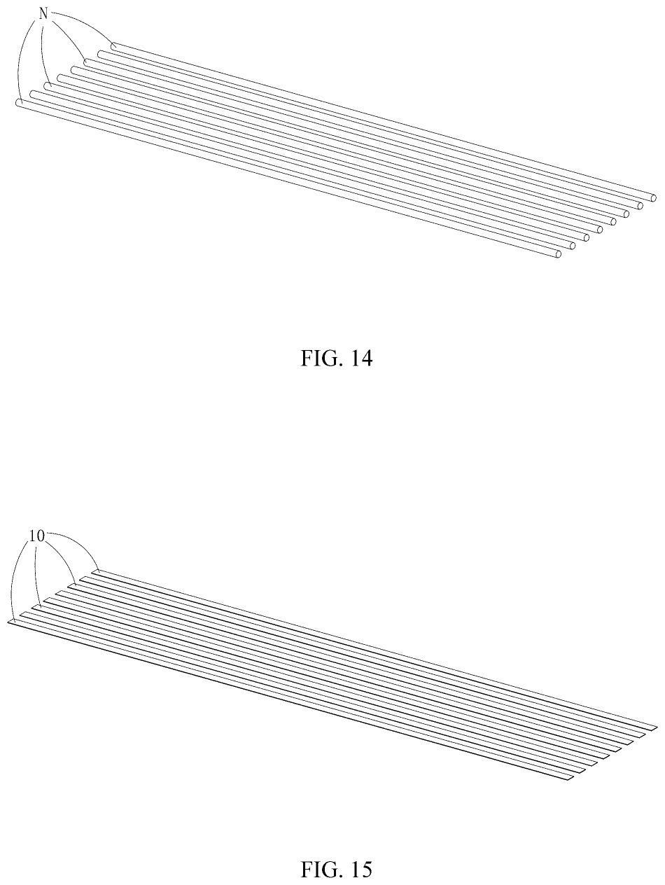

Please refer to FIG. 13, which is a flowchart of a manufacturing method of a flexible flat connection cable with an effect of circuit protection according to another embodiment of the present disclosure. Please refer to FIG. 14 to FIG. 18, which are the schematic view diagrams implementing the manufacturing method of FIG. 13 by stamping techniques, etching techniques or laser engraving techniques. First, step S11 is the conductive bulk provision step, and in step S11, the conductive bulk N is provided. As shown in FIG. 14, the conductive bulk N is a plurality of conductive wires, and each of the plurality of conductive wires has a circle cross section. Step S12 is subsequently performed.

Step S12 is a wire pressing extension step. In step S12, as shown in FIG. 15, the plurality of conductive wires are pressed and extended to form a plurality of flexible flat conductive wires 10 so that the cross section of each of the plurality of conductive wires changes from the circle to the rectangle. Step S13 is subsequently performed.

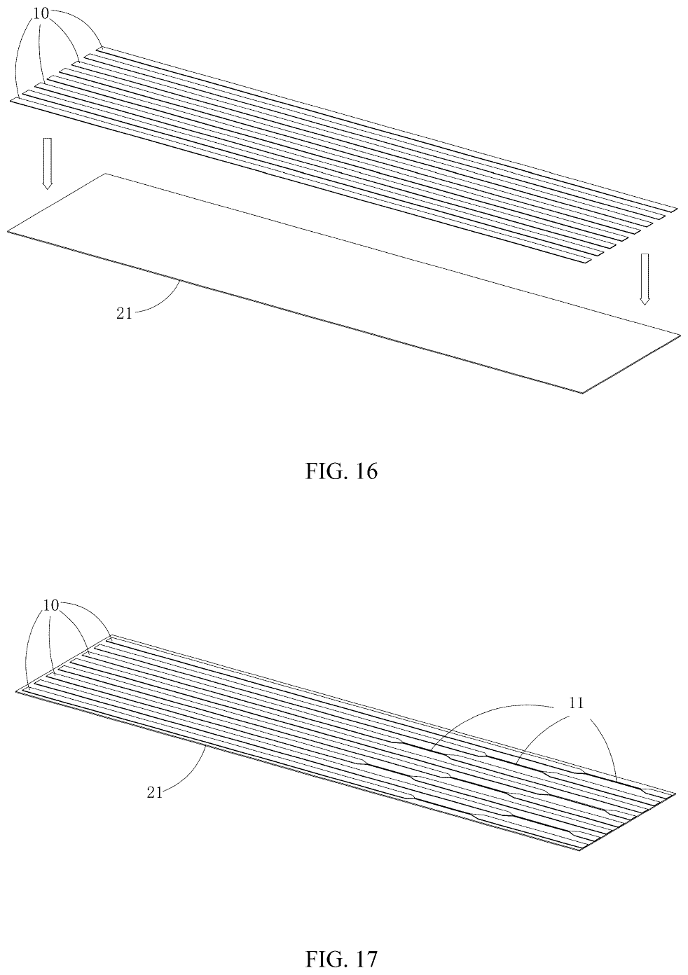

Step S13 is a flexible flat conductive wire positioning step. In step S13, as shown in FIG. 16, the plurality of flexible flat conductive wires 10 would be attached to and positioned on the first insulation sheet 21 so that the plurality of flexible flat conductive wires 10 form a positioning state with each other. Step S14 is subsequently performed.

Step S14 is the circuit protection structure formation step. In step S14, as shown in FIG. 17, the recessions are formed on two sides of the plurality of flexible flat conductive wires 10 by the stamping techniques, the etching techniques or the laser engraving techniques to obtain the plurality of separate circuit protection structures 11, and each of the plurality of circuit protection structures 11 includes the circuit protection part 112, the two circuit conductive parts 111 respectively connected to two sides of the circuit protection part 112, and the circuit connection part 113 connected to the circuit protection part 112 and the circuit conductive part 111. In some embodiments, each flexible flat conductive wire 10 and the corresponding circuit protection structure 11 form the integrally stamped component, the integrally etched component or the integrally laser engraved component by the stamping techniques, the etching techniques or the laser engraving techniques. Step S15 is subsequently performed.

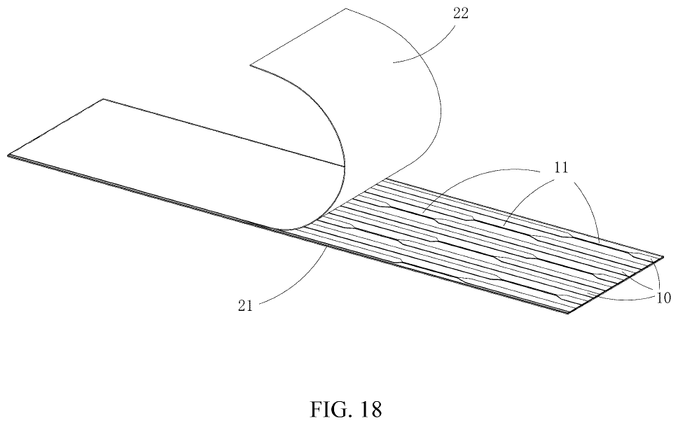

Step S15 is the insulation covering component formation step. In step S15, as shown in FIG. 18, the second insulation sheet 22 would be pressed on the plurality of flexible flat conductive wires 10 and the first insulation sheet 21 by the hot pressing techniques to form the insulation covering component 20 which entirely encompasses the plurality of circuit protection structures 11.

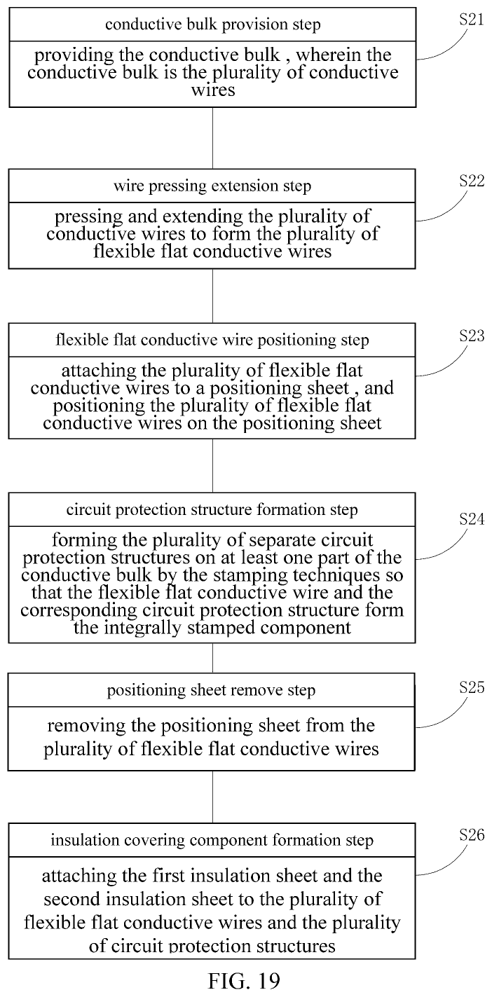

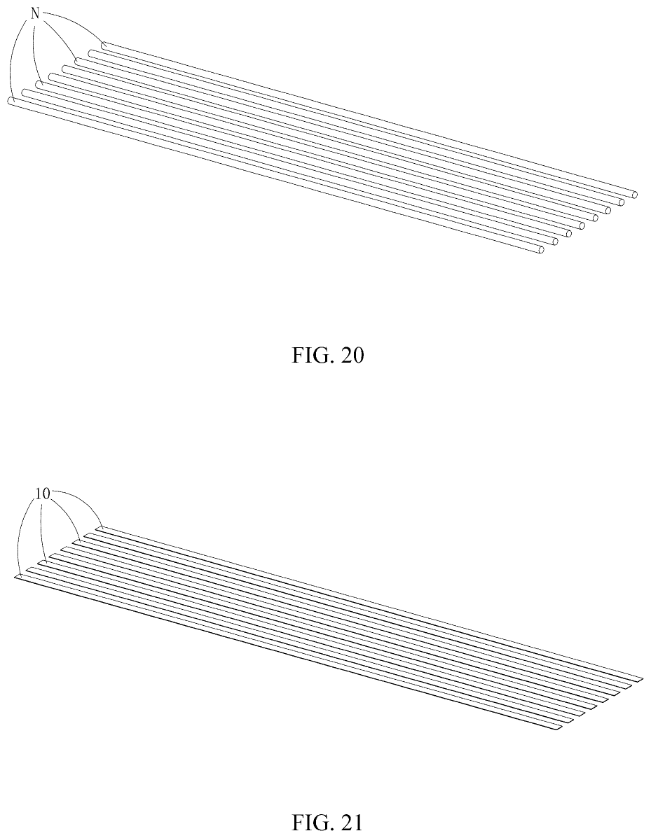

Please refer to FIG. 19, which is a flowchart of a manufacturing method of a flexible flat connection cable with an effect of circuit protection according to yet another embodiment of the present disclosure. Please refer to FIG. 20 to FIG. 25, which are the schematic view diagrams implementing the manufacturing method of FIG. 13 by stamping techniques. Step S21 and step S22 are the same as step S11 and step S12 in the above embodiment.

Step S21 is the conductive bulk provision step. In step S21, as shown in FIG. 20, a plurality of the conductive bulks N are provided, the plurality of the conductive bulks N are the plurality of conductive wires, and each of the plurality of conductive wires has a circle cross section. Step S22 is subsequently performed.

Step S22 is the wire pressing extension step. In step S22, as shown in FIG. 21, the plurality of conductive wires are pressed and extended to form a plurality of flexible flat conductive wires 10 so that the cross section of each of the plurality of conductive wires changes from the circle to the rectangle. Step S23 is subsequently performed.

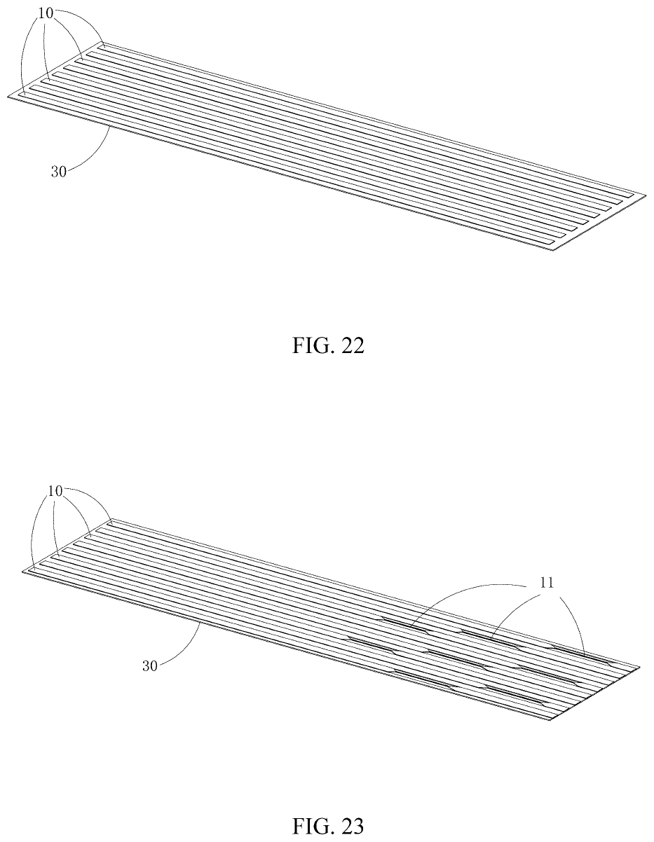

Step S23 is the flexible flat conductive wire positioning step. In step S23, as shown in FIG. 22, the plurality of flexible flat conductive wires 10 would be attached to a positioning sheet 30 so that the plurality of flexible flat conductive wires 10 are positioned on the positioning sheet 30 and there are preset distances among the plurality of flexible flat conductive wires 10. One positioning sheet 30 may be used to attach to one side of the plurality of flexible flat conductive wires 10, or two positioning sheets 30 may be used to attach to two sides of the plurality of flexible flat conductive wires 10. Step S24 is subsequently performed.

Step 24 is the circuit protection structure formation step. In step S24, as shown in FIG. 23, the recessions are formed on two sides of the plurality of flexible flat conductive wires 10 by the stamping techniques to obtain the plurality of separate circuit protection structures 11, each flexible flat conductive wire 10 and the corresponding circuit protection structure 11 form the integrally stamped component, and the perforations are synchronously formed on two sides of the circuit protection structure 11 by the positioning sheet 30. Step S25 is subsequently performed.

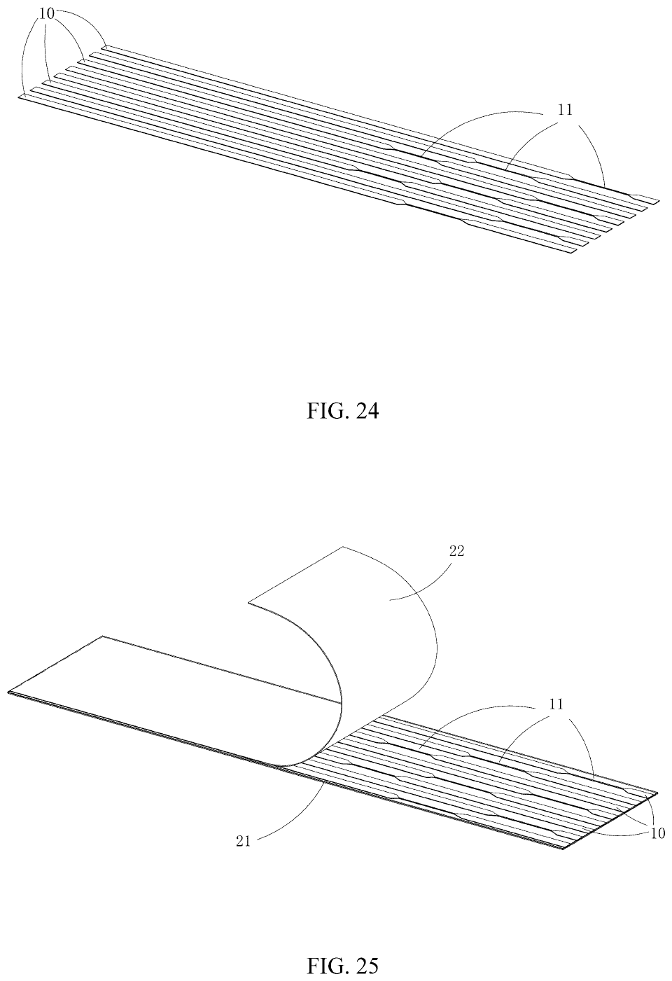

Step S25 is a positioning sheet remove step. In step S25, as shown in FIG. 24, the positioning sheet 30 is removed from the plurality of flexible flat conductive wires 10. Step S26 is subsequently performed.

Step S26 is the insulation covering component formation step. In step S26, as shown in FIG. 25, the first insulation sheet 21 and the second insulation sheet 22 would be pressed on the plurality of flexible flat conductive wires 10 and the plurality of circuit protection structures 11 by the hot pressing techniques, for example, and the insulation covering component 20 which entirely encompasses the plurality of circuit protection structures 11 is formed.

In another embodiment, the positioning sheet remove step of step S25 may be omitted, step S26 is directly entered from step S24, and the first insulation sheet 21 and the second insulation sheet 22 directly cover the positioning sheet 30. Afterwards, the first insulation sheet 21 and the second insulation sheet 22 together with the positioning sheet 30 are pressed on the plurality of flexible flat conductive wires 10 and the plurality of circuit protection structures 11 by the hot pressing techniques. In some embodiments, in the situation that there is one positioning sheet 30, the positioning sheet remove step of step S25 may be that the first insulation sheet 21 is attached to one side of the plurality of flexible flat conductive wires 10 and the circuit protection structures 11 which does not have the positioning sheet 30, the positioning sheet 30 is removed and the second insulation sheet 22 is attached; in the situation that there is two positioning sheets 30, the positioning sheet remove step of step S25 may be that one positioning sheet 30 is removed, the first insulation sheet 21 is attached to one side of the plurality of flexible flat conductive wires 10 and the circuit protection structures 11 where one positioning sheet is removed, the other positioning sheet 30 is removed and the second insulation sheet 22 is attached.

Hence, the flexible flat connection cables 1 with the effect of circuit protection shown in FIG. 1 and FIG. 2 may be obtained by the embodiments of three manufacturing methods shown in FIG. 3, FIG. 13 or FIG. 19.

It is to be understood that the term “includes”, “including”, or any other variants thereof, is intended to encompass a non-exclusive inclusion, such that a process, method, article, or device of a series of elements not only include those elements but also includes other elements that are not explicitly listed, or elements that are inherent to such a process, method, article, or device. An element defined by the phrase “including a . . . ” does not exclude the presence of the same element in the process, method, article, or device that includes the element.

The above descriptions combine accompanying drawings to describe the embodiments of the present disclosure, but the present disclosure is not limited to the above specific implementation, and the above specific implementation is schematic instead of restrictive. Under the teaching of the present disclosure, the modification made by a person in the art without departing from the protection scope of the aim of the present disclosure and the appended claims shall fall within the protection of the present disclosure.

What is claimed is:

1. A flexible flat connection cable with an effect of circuit protection comprising:
a plurality of flexible flat conductive wires arranged to extend in parallel to each other and be separated by preset intervals, each of the plurality of flexible flat conductive wires comprising at least one circuit protection structure, wherein the at least one circuit protection structure comprises two circuit conductive parts, a circuit protection part disposed between the two circuit conductive parts, and two circuit connection parts respectively connected between the two circuit conductive parts and the circuit protection part, the circuit conductive part has a first line width, the circuit protection part has a second line width, and the first line width is greater than the second line width; and
an insulation covering component covering the circuit protection structures of the plurality of flexible flat conductive wires, wherein the plurality of flexible flat conductive wires are disposed within the insulation covering component;
wherein a position of the circuit protection part of each of the plurality of flexible flat conductive wires and a position of the circuit protection part of the adjacent flexible flat conductive wire are staggered in a direction orthogonal to an extending direction of the flexible flat conductive wire.

2. The flexible flat connection cable with the effect of the circuit protection according to claim 1, wherein the positions of the circuit protection parts of the plurality of flexible flat conductive wires are all staggered in the direction orthogonal to the extending direction of the flexible flat conductive wire.

3. The flexible flat connection cable with the effect of the circuit protection according to claim 1, wherein a line width of each of the circuit connection parts gradually increases from one end connected to the circuit protection part to one end connected to the circuit conductive part.

4. The flexible flat connection cable with the effect of the circuit protection according to claim 3, wherein each of the circuit connection parts exhibits a cone, and a conical degree range of the cone is 30 degrees to 60 degrees.

5. The flexible flat connection cable with the effect of the circuit protection according to claim 3, wherein the second line width is one eighth to one twelfth of the first line width.

6. The flexible flat connection cable with the effect of the circuit protection according to claim 4, wherein the second line width is one tenth of the first line width, and the second line width is equal to a thickness of each of the plurality of flexible flat conductive wires.

7. The flexible flat connection cable with the effect of the circuit protection according to claim 1, wherein the insulation covering component comprises a first insulation sheet and a second insulation sheet which are relatively disposed, and the first insulation sheet and the second insulation sheet are clamped and encompass the plurality of flexible flat conductive wires.

8. The flexible flat connection cable with the effect of the circuit protection according to claim 1, wherein each of the plurality of flexible flat conductive wires and the corresponding circuit protection structure are an integrally stamped component, an integrally etched component or an integrally laser engraved component.

9. A manufacturing method of a flexible flat connection cable with an effect of circuit protection comprising steps as follows:
a conductive bulk provision step: providing a conductive bulk;
a circuit protection structure formation step: forming a plurality of separate circuit protection structures on at least one part of the conductive bulk, wherein each of the plurality of circuit protection structures comprises a circuit protection part, two circuit conductive parts respectively connected to two sides of the circuit protection part, and two circuit connection parts connected between the circuit protection part and the two circuit conductive parts; and
an insulation covering component formation step: forming an insulation covering component which encompasses the plurality of circuit protection structures;
wherein the circuit conductive part has a first line width, the circuit protection part has a second line width, the first line width is greater than the second line width, and a position of the circuit protection part of each of the plurality of circuit protection structures and a position of the circuit protection part of the adjacent circuit protection structure are staggered in a direction orthogonal to an extending direction of the circuit conductive part.

10. The manufacturing method of the flexible flat connection cable with the effect of the circuit protection according to claim 9, wherein the conductive bulk is a conductive plate, and the manufacturing method further comprises a flexible flat conductive wire formation step: continuing and forming the circuit conductive parts on a part of the conductive bulk except the plurality of circuit protection structures so that the circuit conductive parts on the two sides of the circuit protection part extend along a direction far away from the circuit protection part to form a plurality of flexible flat conductive wires.

11. The manufacturing method of the flexible flat connection cable with the effect of the circuit protection according to claim 10, wherein the insulation covering component formation step comprises:
attaching the plurality of flexible flat conductive wires with the plurality of circuit protection structures to a first insulation sheet;
pressing a second insulation sheet on the plurality of flexible flat conductive wires and the first insulation sheet.

12. The manufacturing method of the flexible flat connection cable with the effect of the circuit protection according to claim 10, wherein the circuit protection structure formation step and the flexible flat conductive wire formation step are respectively implemented by a double continuous stamped process.

13. The manufacturing method of the flexible flat connection cable with the effect of the circuit protection according to claim 10, wherein the circuit protection structure formation step and the flexible flat conductive wire formation step are implemented by etching techniques or laser engraving techniques, and the circuit protection structure formation step and the flexible flat conductive wire formation step are synchronously complete.

14. The manufacturing method of the flexible flat connection cable with the effect of the circuit protection according to claim 9, wherein the conductive bulk is a plurality of conductive wires, and the manufacturing method further comprises a wire pressing extension step: pressing and extending the plurality of conductive wires to form a plurality of flexible flat conductive wires; wherein each of the plurality of separate circuit protection structures respectively forms on each of the plurality of flexible flat conductive wires.

15. The manufacturing method of the flexible flat connection cable with the effect of the circuit protection according to claim 14, wherein the circuit protection structure formation step is implemented by stamping techniques, etching techniques or laser engraving techniques.

16. The manufacturing method of the flexible flat connection cable with the effect of the circuit protection according to claim 14, wherein each of the plurality of flexible flat conductive wires and the corresponding circuit protection structure form an integrally stamped component, an integrally etched component or an integrally laser engraved component by stamping, etching or laser engraving.

17. The manufacturing method of the flexible flat connection cable with the effect of the circuit protection according to claim 14, further comprising a flexible flat conductive wire positioning step: attaching the plurality of flexible flat conductive wires to a first insulation sheet, and positioning the plurality of flexible flat conductive wires on the first insulation sheet; wherein the insulation covering component formation step further comprises: attaching a second insulation sheet to the plurality of flexible flat conductive wires and the first insulation sheet.

18. The manufacturing method of the flexible flat connection cable with the effect of the circuit protection according to claim 14, further comprising:
a flexible flat conductive wire positioning step: attaching the plurality of flexible flat conductive wires to a positioning sheet, and positioning the plurality of flexible flat conductive wires on the positioning sheet;
wherein the circuit protection structure formation step further comprises: forming the circuit protection structure on each of the plurality of flexible flat conductive wires by stamping techniques so that the flexible flat conductive wire and the circuit protection structure become an integrally stamped component;
wherein the insulation covering component formation step further comprises: attaching a first insulation sheet and a second insulation sheet to the plurality of flexible flat conductive wires and the plurality of circuit protection structures.

19. The manufacturing method of the flexible flat connection cable with the effect of the circuit protection according to claim 18, further comprising: a positioning sheet remove step: removing the positioning sheet after forming the plurality of circuit protection structures.

20. The manufacturing method of the flexible flat connection cable with the effect of the circuit protection according to claim 9, wherein a line width of each of the circuit connection parts gradually increases from one end connected to the circuit protection part to one end connected to the circuit conductive part.
